(19) United States
(12) Patent Application Publication
(10) Pub. No.: US 2009/0074355 A1
(43) Pub. Date: Mar. 19, 2009

(54) Photonically-coupled nanoparticle quantum systems and methods for fabricating the same

(76) Inventors: Raymond G. Beausoleil, Redmond, WA (US); David A. Fattal, Mountain View, CA (US); Charles M. Santori, Palo Alto, CA (US); Sean M. Spillane, Mountain View, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/901,350

(22) Filed: Sep. 17, 2007

(51) Int. Cl. G02B 6/26; H01L 21/00

(52) U.S. Cl. 385/27; 438/47

(57) ABSTRACT

Various embodiments of the present invention are directed to photonically-coupled quantum dot systems. In one embodiment of the present invention, a photonic device comprises a top layer, a bottom layer, and a transmission layer positioned between the top layer and the bottom layer and configured to transmit electromagnetic radiation. The photonic devices may also include at least one quantum system embedded within the transmission layer. The at least one quantum system can be positioned to receive electromagnetic radiation and configured to emit electromagnetic radiation that propagates within the transmission layer.

### STATEMENT OF GOVERNMENT INTEREST

This invention has been made with Government support under Contract No. FA9550-05-C-0017, awarded by the Defense Advanced Research Projects Agency. The government has certain rights in the invention.

### TECHNICAL FIELD

The present invention relates to photonically-coupled nanoparticle quantum systems, and, in particular, to photonic devices including photonically-coupled nanoparticle quantum systems and methods for fabricating the same.

### BACKGROUND

In recent years, the fields of quantum computation and quantum information science have stimulated considerable interest in fabricating nanoscale devices that are capable of strong, coherent coupling between individual quantum systems and photons. Strong, coherent coupling between quantum systems and photons may enable quantum information to be passed over relatively long distances and provide long-range interactions between quantum systems. A number of potentially promising devices based on atomic physics and quantum optics as wells as mesoscopic solid-state physics have been investigated. However, many of these devices only provide photonic coupling between quantum systems via relatively short-range interactions. An example of a device that may provide strong coupling with and relatively longer range coherent coupling between individual quantum systems is described in the followings references: “Cavity Quantum electrodynamics with surface plasmons,” by Chang et al., preprint: http://arxiv.org/abs/quant-ph/0506117v2; “Strong coupling of single emitters to surface plasmons,” by Chang et al., preprint: http://arxiv.org/abs/quant-ph/0603221v1; and “Quantum optics with surface plasmons,” by Chang et al., preprint: http://arxiv.org/abs/quant-ph/0506117v1. The device of Chang is comprised of a quantum system coupled to a nanowire, which, in turn, is evanescently coupled to a dielectric waveguide. An external photonic source can be used to excite the quantum system into an excited electronic state, which then decays into plasmon modes of the nanowire. The nanowire thus increases the coupling of photons to the quantum system, and transmits the photons emitted by the quantum system into the waveguide by evanescently coupling the plasmon modes carried along the nanowire surface into the nearby dielectric waveguide. While surface plasmons do provide the possibility of strong coupling of photons to matter, their propagation length is usually limited to a few tens of microns. Therefore devices providing longer range coupling interactions are needed.

### SUMMARY

Various embodiments of the present invention are directed to photonically-coupled quantum dot systems. In one embodiment of the present invention, a photonic device comprises a top layer, a bottom layer, and a transmission layer positioned between the top layer and the bottom layer and configured to transmit electromagnetic radiation. The photonic devices may also include at least one quantum system embedded within the transmission layer. The at least one quantum system can be positioned to receive electromagnetic radiation and configured to emit electromagnetic radiation that propagates within the transmission layer.

### BRIEF DESCRIPTION OF THE DRAWINGS

FIG. 1A shows a unit cell of a diamond-crystal lattice.

FIG. 1B shows a nitrogen-vacancy center surrounded by a diamond-crystal lattice.

FIG. 1C illustrates an energy-level diagram of a negatively charged nitrogen-vacancy center.

FIG. 2A shows an energy-level diagram representing a number of quantized energy levels of a hypothetical quantum dot.

FIG. 2B shows two different energy-level diagrams.

FIG. 3A shows an isometric view of a first photonic device in accordance with embodiments of the present invention.

FIG. 3B shows a cross-sectional view of the first photonic device along a line 3B-3B, shown in FIG. 3A, in accordance with embodiments of the present invention.

FIG. 4A shows an isometric view of a second photonic device in accordance with embodiments of the present invention.

FIG. 4B shows a cross-sectional view of the second photonic device along a line 4B-4B, shown in FIG. 4A, in accordance with embodiments of the present invention.

FIG. 5 shows an energy-level diagram associated with a three-level quantum dot.

FIG. 6 shows an energy-level diagram associated with a four-level quantum dot.

FIG. 7A shows a first photonic antenna in accordance with embodiments of the present invention.

FIG. 7B shows a second photonic antenna in accordance with embodiments of the present invention.

FIG. 8 shows a schematic representation of using a photonic antenna in accordance with embodiments of the present invention.

FIG. 9A shows an isometric view of a third photonic device that couples two quantum systems in accordance with an embodiment of the present invention.

FIG. 9B shows a cross-sectional view of the third photonic device along a line 9B-9B, shown in FIG. 8A, in accordance with embodiments of the present invention.

FIG. 10A shows an isometric view of a fourth photonic device that couples two quantum systems in accordance with an embodiment of the present invention.

FIG. 10B shows a cross-sectional view of the fourth photonic device along a line 10B-10B, shown in FIG. 10A, in accordance with embodiments of the present invention.

FIGS. 11A-11G show isometric and cross-sectional views associated with a method of fabricating the layers and quantum systems of the first photonic device, shown in FIG. 3, in accordance with embodiments of the present invention.

### DETAILED DESCRIPTION

Various embodiments of the present invention are directed to photonic devices that can be used to couple quantum systems with electromagnetic radiation. These photonic devices include a transmission layer and a number of quantum systems (“QSs”) that are optically active and distributed within the transmission layer. The QSs can be configured and positioned within the transmission layer to receive and emit electromagnetic radiation that propagates within the transmission layer. Photonic device embodiments of the present invention can be used as photonic antenna that are configured to receive and transmit data encoded in electromagnetic radiation to other photonic and electronic devices for processing.

The terms “photonic” and “photonically” refer to devices that operate with classical electromagnetic radiation or quantized electromagnetic radiation with frequencies spanning the electromagnetic spectrum. The QSs used in photonic device embodiments of the present invention can be nanoparticle color centers and quantum dots, which are described below in a first subsection. Other examples of optically active systems include impurity-bound excitons in semiconductors, atoms or ions. Embodiments of the present invention are described below in a second subsection. In the various embodiments of the present invention described below, a number of structurally similar components comprising the same materials have been identified by the same reference numerals and, in the interest of brevity, an explanation of their structure and function is not repeated.

### Quantum Systems

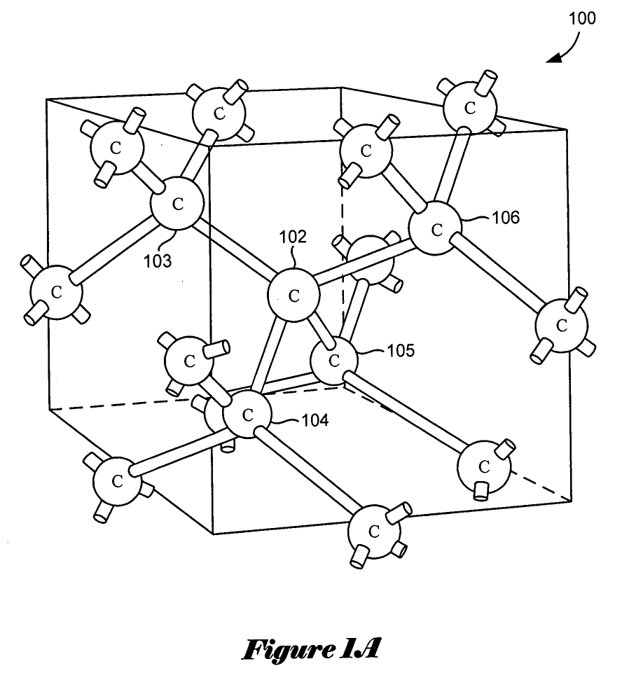

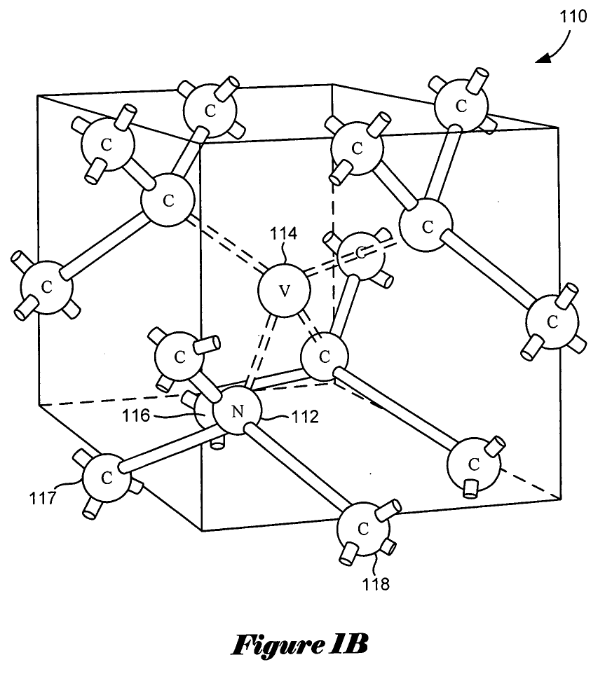

A nanoparticle color center is a diamond crystal that includes impurities and defects, called “color centers,” embedded in the diamond. Diamond has a crystal lattice structure comprising two interpenetrating face-centered cubic lattices of carbon atoms. FIG. 1A shows a unit cell 100 of a diamond-crystal lattice. In FIG. 1A, each carbon atom, represented by a sphere, is covalently bonded to four adjacent carbon atoms, each covalent bond is represented by a rod connecting two spheres. As shown in FIG. 1A, a carbon atom 102 is covalently bonded to four carbon atoms 103-106. Color centers are now described with reference to a nitrogen-vacancy (“NV”) center embedded in diamond. Note, however, that a color center can also be comprised of Ni, Si or another suitable atom that can be used to store a quantum bit of information. FIG. 1B shows an NV center embedded in a diamond-crystal lattice 110. The NV-center comprises a nitrogen atom 112, substituted for a carbon atom, next to a vacancy 114 in the carbon lattice. The nitrogen atom 112 is covalently bonded to three carbon atoms 116-118. NV centers can be created in a nitrogen rich diamond by irradiation and subsequent annealing at temperatures above 550° C. The radiation creates vacancies in the diamond and subsequent annealing causes the vacancies to migrate towards nitrogen atoms to produce NV centers. Alternatively, NV centers can be created in diamond using N⁺ ion implantation.

When an electromagnetic field interacts with an NV center, there is a periodic exhange, or oscillation, of energy between the electromagnetic field and the electronic energy levels of the NV center. Such oscillations, which are called “Rabi oscillations,” are associated with oscillations of the NV center electronic energy level populations and quantum-mechanical probability amplitudes of the NV center electronic energy states. Rabi oscillations can be interpreted as an oscillation between absorption and stimulated emission of photons. The Rabi frequency, denoted by Ω, represents the number of times these oscillations occur per unit time (multiplied by the quantity 2π).

FIG. 1C illustrates an energy-level diagram of electronic states of a negatively charged NV center. Under applied stress or an elecric field, the ³E excited states, which have an optical doublet, spin striplet structure, split into upper and lower branches with different orbital states. Only the lower branch of the excited states, consisting of three spin levels, is shown in the FIG. 1C. Normally, the optical transitions are normally spin converging. However, when the orbital splitting induced by the applied stress or electric field is in a range from about 15 GHz to about 45 GHz, the spin-orbit interaction can mix the excited states so that spin-non-conserving transitions become allowed In this case, it may be possible to obtain Λ-type configuraion comprising multiple ground states coupled to a common excited state. The three ground ³A₂ states comprise a first ground state |1 [symbol] with a lowest energy level 122, and a pair of nearly degenerate ground states |2 [symbol] and |3 [symbol] with energy levels 124 and 126, respectively. In FIG. 1C, all three ground states are coupled to an excited state 128, labeled |4 [symbol] . Double-headed directional arrows 130-131 correspond to optical transitions driven by two laser frequencies. A first laser drives the |1 [symbol] →|4 [symbol] transition, while a second laser drives both the |2 [symbol] →|4 [symbol] and the |3 [symbol] →|4 [symbol] transitions. A parameter δ₁ represents the laser frequency detuning for a |1 [symbol] →|4 [symbol] transition, a parameter δ₂ is the laser frequency detuning for a |2 [symbol] →|4 [symbol] transition, a parameter δ₂₃ is the |2 [symbol] [symbol] |3 [symbol] energy splitting, and Ωᵢ represent Rabi frequencies, which are proportional to the square root of the laser intensities. When δ₁=δ₂ or δ₁=δ₂+δ₃, the system will relax through spontaneous emission into stable “dark” states, which are linear combinations of the states |1 [symbol] , |2 [symbol] , and |3 [symbol] , with probability amplitudes that are tunable through the laser amplitudes. These dark resonance states can be used, for example, for all-optical manipulation of the electron spin. For a description of experimental investigations of NV centers, see “The nitrogen-vacancy center in diamond re-visted,” by N. B. Manson et al., preprint: http://arxiv.org/abs/cond-mat/0601360; “Coherent population trapping with a single spin in diamond,” by Charles Santori et al., preprint: http://arxiv.org/abs/quant-ph/0607147; and “Coherent population trapping in Diamond N-V centers at zero magnetic field,” by Charles Santori et al., preprint: http://arxiv.org/abs/cond-mat/0602573. Note that the exact structure of the ³E state depends on the strain or other mechanical effects exterted on the diamond crystal. Also, the excited-state linewidths depend critically on the temperature. In order to obtain optical linewidths that are less than 100 MHz, it is necessary to lower the temperature of the diamond crystal to temperatures below 20K. With narrow optical linewidths, it is possible to manipulate the spins of single NV centers using the optical transitions shown in FIG. 1C.

The NV centers are appealing for quantum information processing because the NV center has a relatively long-lived spin coherence time and a possibility of large-scale integration into semiconductor processing technology. For example, an NV center electron spin coherence time of 58 μs has been observed at room temperature. See “Long coherence times at 300K for nitrogen-vacancy center spins in diamond grown by chemical vapor deposition,” by A. Kennedy et al., App. Phys. Lett. 83, 4190-4192 (2003). NV centers may have relatively long-lived spin coherence because the lattice comprises primarily ¹²C, which has zero nuclear spin. In addition, a single photon can be generated from an NV center at room temperature, which has established NV centers as potential photon sources for quantum cryptography. See “Stable solid-state source of single photons,” by C. Kurtsiefer et al., Phys. Rev. Lett. 85, 290-293 (2000) and “Room temperature stable single photon source,” by A. Beveratos et al., Eur. Phys. J. D 18, 191-196 (2002).

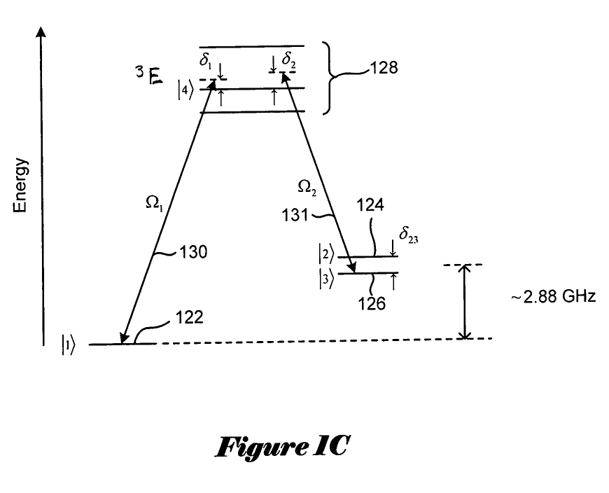

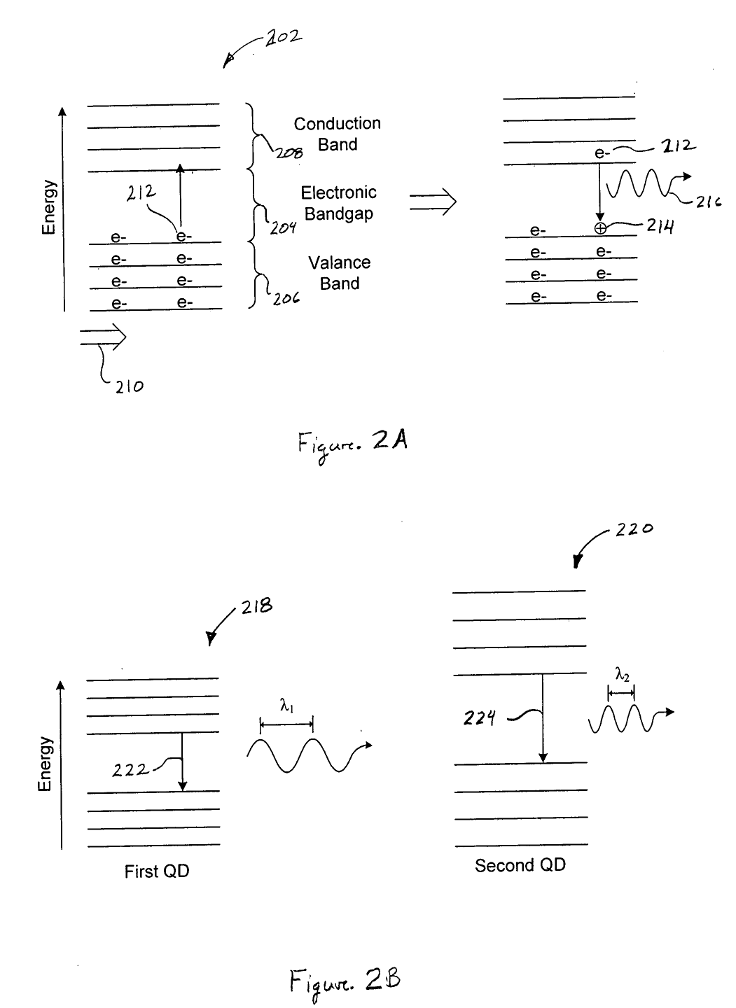

A quantum dot (“QD”), on the other hand, can generally be comprised of from about 10 to about 50 atoms, may range in diameter from about 2 to about 10 nanometers, and may be comprised of a number of different materials. For example, a QD can be a CdSe nanocrystal or a nucleated QD comprised of a suitable III-V semiconductor, such as AlGaAs. A QD has a number of quantized electronic energy levels, and only two electrons can occupy any one energy level. FIG. 2A shows an energy-level diagram 202 representing a number of quantized energy levels of a hypothetical QD. In energy-level diagram 202, each quantized energy level is represented by a horizontal line, and the quantum energy levels are arranged vertically in order of increasing energy. The quantized energy levels of a semiconductor include an inaccessible range of energies called an “electronic bandgap” 204. Electrons occupying energy levels below the electronic bandgap 204 are said to be in a valance band 206, and electrons occupying energy levels above the electronic bandgap 204 are said to be in a conduction band 208. As shown in FIG. 2A, the lowest possible electronic energy level of the QD occurs when pairs of electrons, each electron denoted by “e-,” occupy the energy levels in the valance band 206.

Applying an appropriate electronic stimulus 210, such as heat, voltage, or electromagnetic radiation, to a QD can change the electronic energy level of the QD. When the magnitude of the energy associated with the electronic stimulus is large enough, one or more electrons can be promoted into a higher energy level in the conduction band. For example, in FIG. 2A, an electron 212 that occupies an energy level in the valance band 206 absorbs the energy associated with an electronic stimulus by jumping into an energy level in the conduction band 208, which leaves a positively charged electron hole 214 in the valance band 206. Note that the minimum energy an electron in the valance band 206 needs to absorb in order to be promoted into an energy level in the conduction band 208 corresponds to the width of the electronic bandgap 204. The electron 212 remains momentarily in an energy level of the conduction band 208 before transitioning back across the electronic bandgap 204 to an energy level in the valance band 206. As the electron 212 transitions from an energy level in the conduction band 208 to an energy level in the valance band 206, electromagnetic radiation 216 corresponding to the energy lost in the transition is emitted. Typically, electrons transition from the lowest energy level of the conduction band to the highest energy level of the valance band. Because the electronic bandgap is fixed for a particular QD, each time this transition occurs electromagnetic radiation of a fixed wavelength is emitted.

The wavelength of the electromagnetic radiation emitted by a QD can, however, be adjusted by changing the number of atoms comprising the QD or changing the shape of the QD. FIG. 2B shows two different energy-level diagrams. In FIG. 2B, each energy-level diagram corresponds to a different hypothetical QD. Both of the QDs have identical chemical compositions, but each QD has a different number of atoms. Energy-level diagram 218 shows the quantized energy levels of a first QD, and energy-level diagram 220 shows the quantized energy levels of a second QD having the same chemical composition as the first QD but with a fewer number of atoms. Note that the energy separations between the quantized energy levels and the electronic bandgap associated with the first QD are smaller than the energy separations between the quantized energy levels and the electronic bandgap associated with the second QD. The wavelength of electromagnetic radiation emitted by the first QD is different from the wavelength of the electromagnetic radiation emitted by the second QD because of the energy difference in the electronic bandgaps. For example, the energy-level diagram 218 shows an energy-level transition 222 resulting in an emission of electromagnetic radiation with a wavelength λ₁, while the energy-level diagram 220 shows an energy-level transition 224 resulting in an emission of electromagnetic radiation with a wavelength λ₂, where λ₂<λ₁.

### EMBODIMENTS OF THE PRESENT INVENTION

FIG. 3A shows an isometric view of a first photonic device 300 in accordance with embodiments of the present invention. Photonic device 300 comprises a transmission layer 302 sandwiched between a top layer 304 and a bottom layer 306. Photonic device 300 includes a substrate 308 that supports layers 302, 304, and 306. Transmission layer 302 includes two QSs 310 and 312, which can be quantum dots, nanoparticle color centers, impurity-bound excitons in semiconductors, atoms, or ions. FIG. 3B shows a cross-sectional view of photonic device 300 along line 3B-3B, shown in FIG. 3A, in accordance with embodiments of the present invention. As shown in FIG. 3B, QSs 310 and 312 are embedded within transmission layer 302 and substantially surrounded by material comprising transmission layer 302. Although QSs 310 and 312 are shown in FIG. 3A as spheres, in other embodiments of the present invention, QSs 310 and 312 can be cubic, elliptical, polyhedral, or any other suitable three-dimensional shape that can be embedded within transmission layer 302.

Layers 302, 304 and 306 form a “slot waveguide” which substantially confines electromagnetic radiation generated by a source (not shown) or emitted from QSs 310 and 312 to transmission layer 302. The dimensions of transmission layer 302 may range form a height H of approximately 30-70 nm and a width W of approximately 130-220 nm, or from a height H of approximately 40-60 nm and a width W of approximately 140-210 nm. Layer 302 has a lower refractive index than layers 304 and 306. For example, the material comprising transmission layer 302 may have a refractive index of approximately 1.5, and the material comprising top and bottom layers 304 and 306 may have a refractive index of approximately 3. Because of the dimensions and contrasting refractive indexes, electromagnetic radiation is concentrated within the relatively thin, lower refractive index transmission layer 302. As a result, the electric field component of the electromagnetic radiation increases which enhances the electric field interaction with the QSs 310 and 312, as described in “Ultrasmall Mode Volumes in Dielectric Optical Microcavities,” Robinson et al., PRL 95, 143901 (2005). Like a surface plasmon guide, this slot waveguide enhances the interaction of electromagnetic radiation with matter, however it can transmit electromagnetic radiation signal over much longer distances.

Layers 304 and 306 and QSs 310 and 312 can be comprised of various combinations of semiconductor materials, such as silicon, germanium, a III-V semiconductor, and a II-VI semiconductor, where the Roman numerals II, III, IV, and V represent elements in the second, third, fifth and sixth columns of the Periodic Table of Elements. For example, the material comprising bottom layer 304 can be a III-V semiconductor GaAs, which comprises equal quantities of Ga, a column III element, and As, a column V element. The II-VI and the III-V semiconductors are not limited to just one column II element and one column VI element or one column III element and one column V element. The semiconductor materials used to fabricate layers 304, and 306 may be comprised of different combinations of elements selected from the elements of columns III and V. For example, layers 304 and 306 can be comprised of InₓGa₁₋ₓAs_{y}P_{1-y}, where x and y range between 0 and 1. The choice of parameters x and y are made to lattice match adjacent layers and are well-known in the art. Transmission layer 302 can be comprised of SiO₂, Al₂O₃, Si₃N₄, a polymer, or another suitable dielectric material having a relatively lower refractive index than, and substantially lattice matches, top and bottom layers 304 and 306.

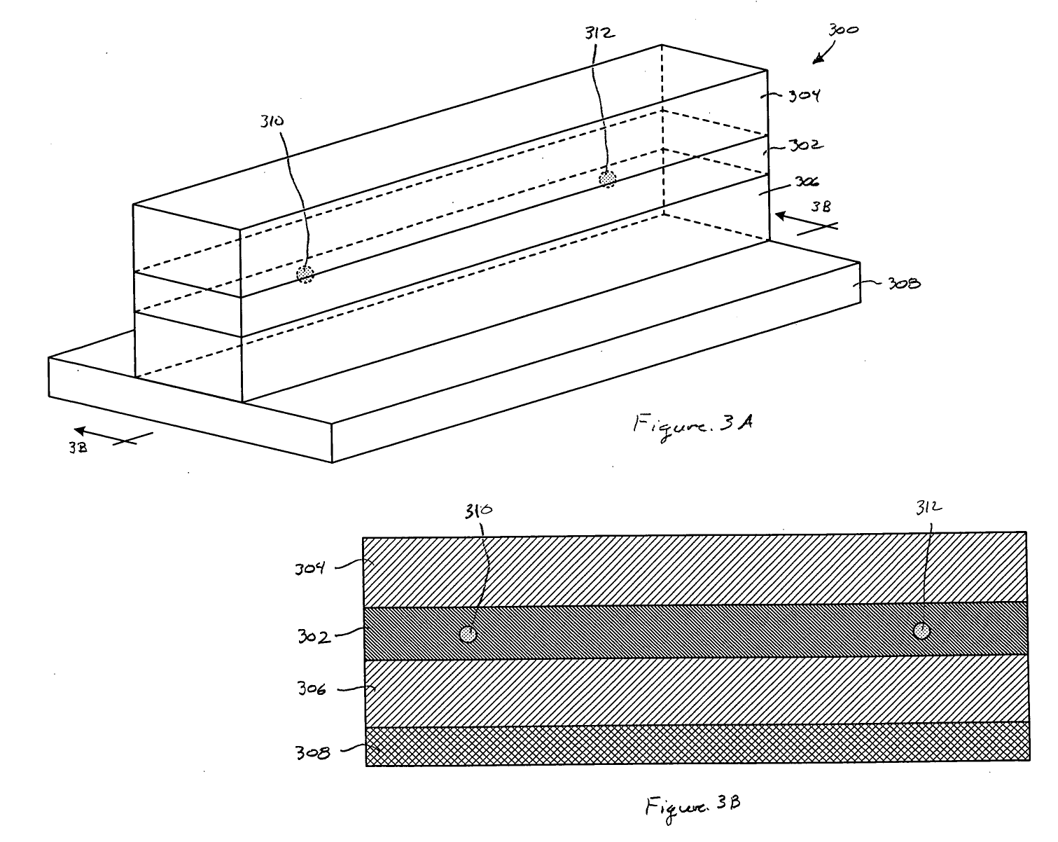

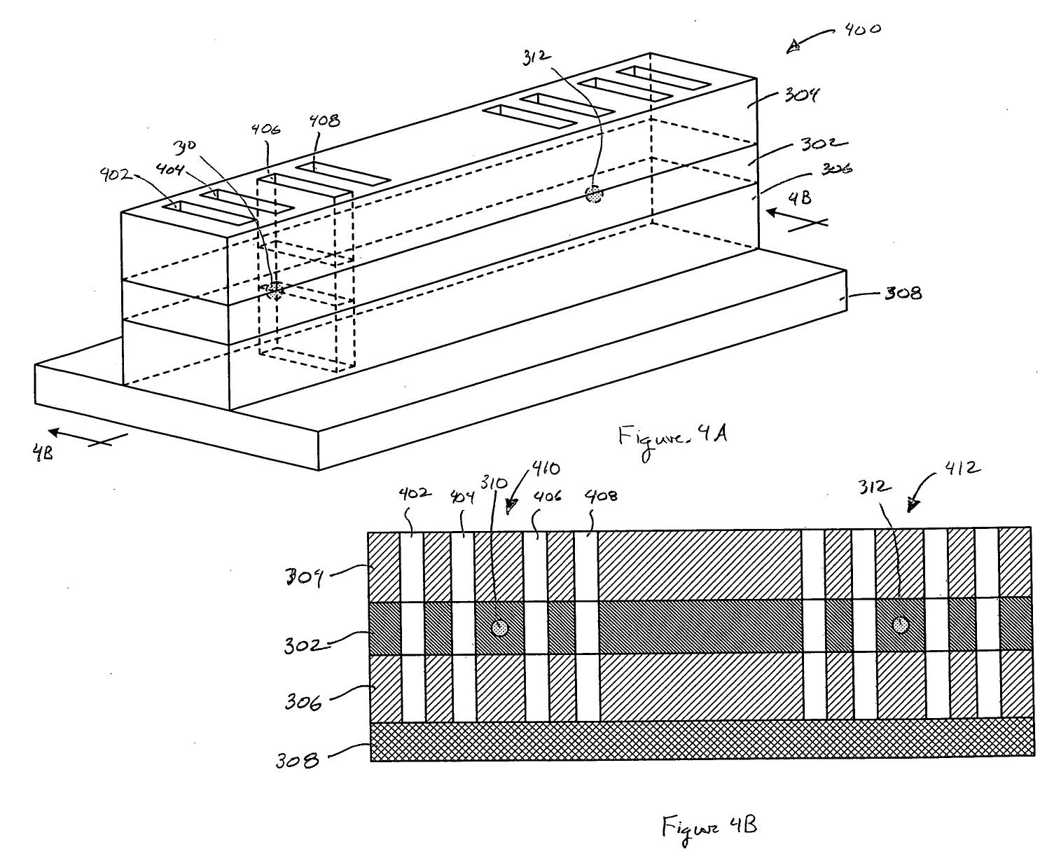

FIG. 4A shows an isometric view of a second photonic device 400 in accordance with embodiments of the present invention. Photonic device 400 comprises a transmission layer 302 sandwiched between top and bottom layers 304 and 306. Two or more holes extend through layers 302, 304, and 306 to substrate 308 and are located in front of, and behind, QSs 310 and 312. The holes define first and second resonant cavities 410 and 412 around QSs 310 and 312. For example, as shown in FIG. 4A, holes 402 and 404 are located on one side of QSs 310 and holes 406 and 408 are located on an opposite side of QSs 310 form first resonant cavity 410 around QS 310. FIG. 4B shows a cross-sectional view of photonic device 400 along line 4B-4B, shown in FIG. 4A, in accordance with embodiments of the present invention. As shown in FIG. 4B, QS 310 is positioned within first resonant cavity 410, and QS 312 is positioned within second resonant cavity 412. The holes forming resonant cavities 410 and 412 trap electromagnetic radiation in a region surrounding QSs 310 and 312 within transmission layer 302. As a result, resonant cavities 410 and 412 increase the quality (“Q”) factor in the region of transmission layer 302 around QSs 310 and 312, which, in turn, increases the intensity of electromagnetic radiation around QSs 310 and 312. Electromagnetic radiation propagates in transmission layer 202 by evanescently coupling out of the resonant cavities into adjacent regions of transmission layer 202. Although the holes shown in FIGS. 4A-4B are rectangular, in other embodiments of the present invention, the holes can be round, square, elliptical, or an other suitable shape for forming a resonant cavity around a QS.

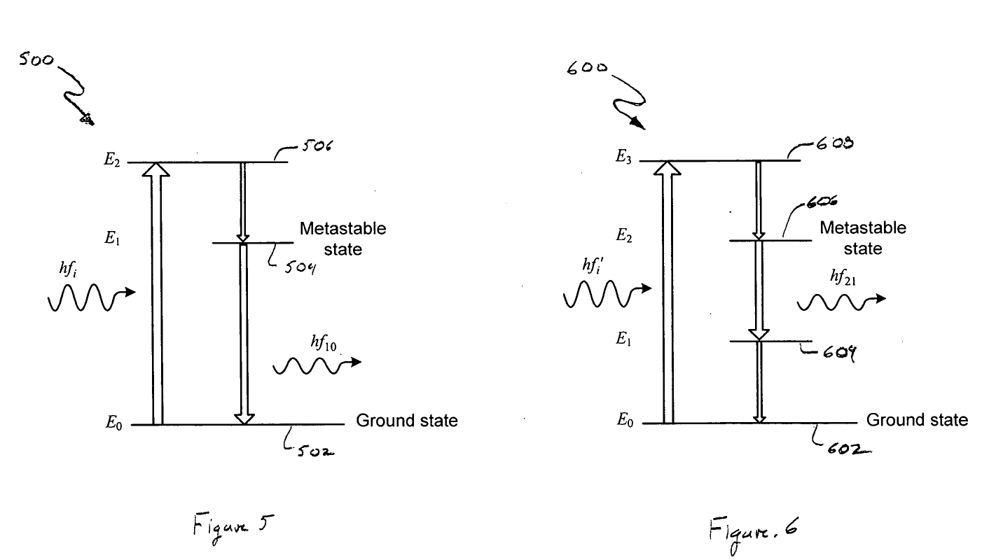

The material, size, and shape of a QD-based QS embedded in a transmission layer can be selected so that the QD-based QS operates as a three-level QD-based QS or a four-level QD-based QS. The following discussion, with reference to FIGS. 5 and 6, is directed to a general description of three- and four-level QD-based QSs. A three-level QD-based QS has three electronic states, each of which is associated with a different electronic energy level. FIG. 5 shows an energy-level diagram 500 associated with a three-level QD-based QS. The energy-level diagram comprises three energy-levels that correspond to three electronic states of the three-level QD-based QS. The three energy levels are comprised of a ground state energy level E₀ 502, a first excited state energy level E₁ 504, and a second excited state energy level E₂ 506. Initially, the QD-based QS is in the ground electronic state, which corresponds to energy level E₀ 502. Applying an appropriate incident electronic stimulus to the QD-based QS causes the QD-based QS to make an electronic energy transition to the higher energy level E₂ 506. This process is called “pumping,” and the incident electronic stimulus can be electromagnetic radiation of a particular frequency fᵢ. The QD-based QS remains in the electronic state associated with the energy level E₂ 506 for a short period of time before spontaneously decaying to the relatively longer lived electronic state, called a “metastable state,” associated with the relatively lower energy level E₁ 504. The QD-based QS may decay into the metastable state via a nonradiative relaxation process, such as emitting acoustic waves. The QD-based QS can transition from the metastable state to the ground state via a spontaneous emission process or a stimulated emission. A spontaneous emission occurs when the QD-based QS spontaneously transitions from the metastable state to the ground state. A stimulated emission occurs as a result of photons stimulating the QD-based QS to transition from the metastable state to the ground state. In both radiative emission processes, the energy of the electromagnetic radiation emitted by the QD-based QS is:

E₁−E₀=hf₁₀

where f₁₀ is the frequency of the emitted electromagnetic radiation.

On the other hand, a four-level QD-based QS has four electronic states, each of which is associated with a different electronic energy level. FIG. 6 shows an energy-level diagram 600 associated with a four-level QD-based QS. The energy-level diagram 600 comprises four energy-levels that correspond to four electronic states of the four-level QD-based QS. The four-energy levels are comprised of a ground state energy level E₀ 602, a first excited state energy level E₁ 604, a second excited state energy level E₂ 606, and a third excited state energy level E₃ 608. Initially, the QD-based QS is in the ground electronic state which corresponds to energy level E₀ 602. The QD-based QS can be pumped into the electronic state associated with energy level E₃ 608 using electromagnetic radiation with a frequency fᵢ′ The QD-based QS remains in this electronic state for a short period of time before decaying in a nonradiative transition to the relatively longer lived metastable state associated with energy level E₂ 606. The QD-based QS transitions from the metastable state to an electronic state associated with the energy level E₁ 604 via a spontaneous or a stimulated emission. The QD-based QS then rapidly decays 616 to the ground state via a nonradiative relaxation process. In both spontaneous and stimulated radiative emissions, the energy of the electromagnetic radiation emitted by the QD-based QS is:

E₂−E₁=hf₂₁

where f₂₁ is the frequency of the emitted electromagnetic radiation.

As long as the pumps are applied to the both the three-level QD-based QS and the four-level QD-based QS, electromagnetic radiation with frequencies f₁₀ and f₂₁ are emitted, respectively. The frequencies fᵢ and fᵢ′ of the pumping stimulus and the frequencies f₁₀ and f₂₁ emitted form the QD-based QS can be selected by tuning the material, size, and shape of the QD-based QSs. For example, each of the excited state energy levels E₁, E₂, and E₃ of the four-level QD-based QS can be increased or decreased according to the selected material, size, and shape of the QD-based QS.

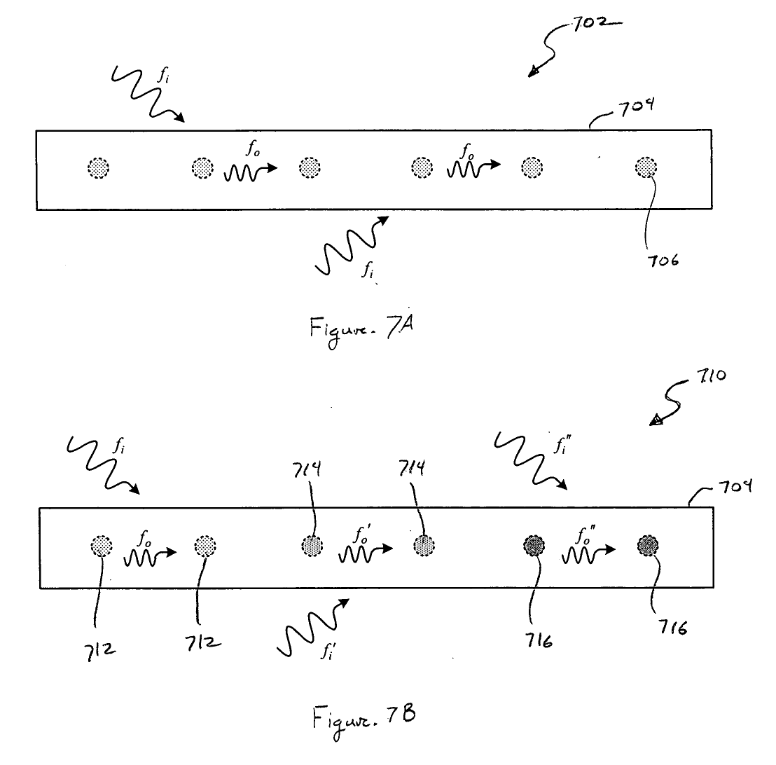

The length, type, and number of QSs embedded in the photonic devices 300 and 400 can vary depending on how the photonic devices 300 and 400 are to be used. In one embodiment of the present invention, the photonic devices 300 and 400 can be configured as photonic antenna for receiving data encoded in electromagnetic radiation and transmitting the data to a computational device for processing. Data can be encoded in the electromagnetic radiation by time varying the intensity of the electromagnetic radiation. FIG. 7A shows a first photonic antenna 702 in accordance with an embodiment of the present invention. Photonic antenna 702 comprises a waveguide 704 and six QSs, such as QS 706, embedded in a transmission layer of a waveguide 704, as described above with reference to FIGS. 3 and 4. In one embodiment of the present invention, the material, size, and shape of the QSs of photonic antenna 702 are selected so that the six QSs can be pumped by the same incident electromagnetic radiation having a frequency fᵢ and output electromagnetic radiation of another frequency fₒ, as described above with reference to FIGS. 5 and 6, which is substantially confined to the waveguide 704. Both the incident electromagnetic radiation and the output electromagnetic radiation may encode the same data.

In other embodiments of the present invention, a photonic antenna can be configured to receive two or more data encoded electromagnetic radiation signals by configuring the QSs with different materials, sizes, and shapes. FIG. 7B shows a second Photonic device-based photonic antenna 710 in accordance with an embodiment of the present invention. Photonic antenna 710 comprises six pairs of QSs 712, 714, and 716 embedded in waveguide 704. The material, size, and shape of QSs 712 are selected so that QSs 712 are pumped by incident electromagnetic radiation having a frequency fᵢ and output electromagnetic radiation with a frequency fₒ. The material, size, and shaped of QSs 714 are selected so that QSs 714 are pumped by incident electromagnetic radiation having a frequency fᵢ′ and output electromagnetic radiation with another frequency fₒ′. The material, size, and shape of QSs 716 are selected so that QSs 716 are pumped by incident electromagnetic radiation having a frequency fᵢ″ and output electromagnetic radiation of another frequency fₒ″. The electromagnetic radiation output from the different QSs 712, 714, and 716 are substantially confined to the waveguide 704 and can be encoded with the same information as the incident electromagnetic radiation.

The photonic devices of the present invention can be configured and operated as photonic antenna that transmits information to a computational device for processing. FIG. 8 shows a schematic representation of using a photonic antenna 802 in accordance with an embodiment of the present invention. Photonic antenna 802 is photonically coupled to a source 804 and a buffer 806. Source 804 can be an electromagnetic radiation source of a first computational device, such as a computer, central processing unit (“CPU”), or memory. Photonic antenna 802 receives data encoded electromagnetic radiation 808 output from source 804, where the data can be encoded in the intensity of the electromagnetic radiation. The frequency with which the data encoded electromagnetic radiation is output from source 804 is selected to pump a number of the QSs in the photonic antenna as described above with reference to FIG. 7A. Photonic antenna 802 outputs data encoded electromagnetic radiation to photonically-coupled buffer 806, which stores the data and transmits blocks of the data via electrical signals to a central processing unit 810 for processing. In other embodiments of the presenting invention, photonic antenna 802 can be configured as described above with reference to FIG. 7B to receive and transmit one or more data encoded signals of electromagnetic radiation output one or more sources.

The fields of quantum computing and quantum information science have stimulated interest in generating coherent interactions between individual QSs. Certain photonic device embodiments of the present invention can be configured to provide coherent coupling between quantum systems that are separated by several centimeters. For example, the separation distance between QSs of a photonic device can be as large as about 3 cm or more and may have losses on the order of 3 dB/cm.

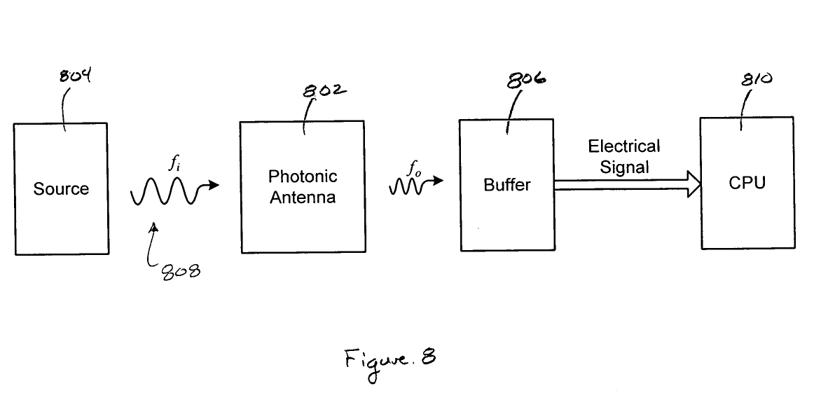

In addition to coupling electronic degrees of freedom of QSs with electromagnetic radiation via the electronic states of the QSs, quantum information can also be stored in the nuclear spin states of certain QSs using via the nuclear spin-electron spin interaction. Suitable radio frequencies can help or prevent the coupling of the electron spin of certain QSs with the nuclear spin of the same or of other QSs. FIG. 9A shows an isometric view of a photonic device 900 that couples two quantum systems in accordance with embodiments of the present invention. Photonic device 900 is identical to photonic device 300, shown in FIG. 3, except for two additional quantum systems 902 and 904 positioned in bottom layer 306 beneath QSs 310 and 312, respectively. FIG. 9B shows a cross-sectional view of photonic device 900 along a line 9B-9B, shown in FIG. 9A, in accordance with an embodiment of the present invention. Radio frequencies can be used to couple the electron spin states of QSs 310 and 312 to nuclear spin states of QSs 902 and 904.

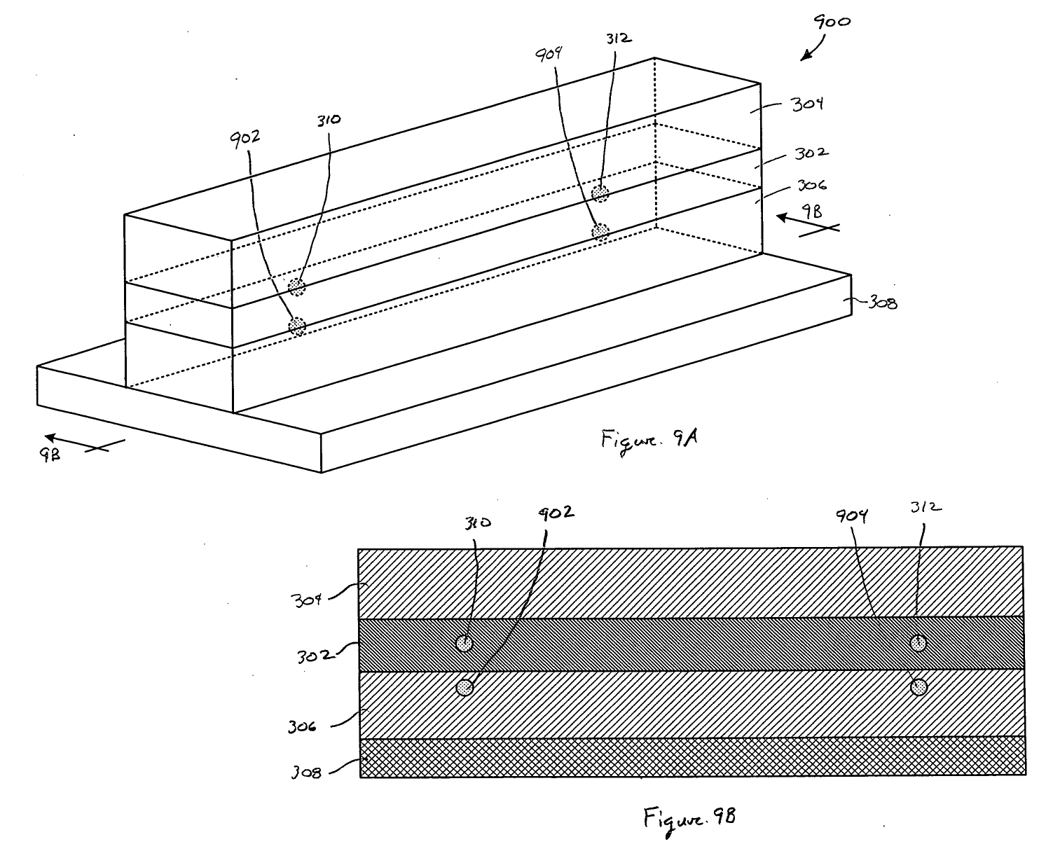

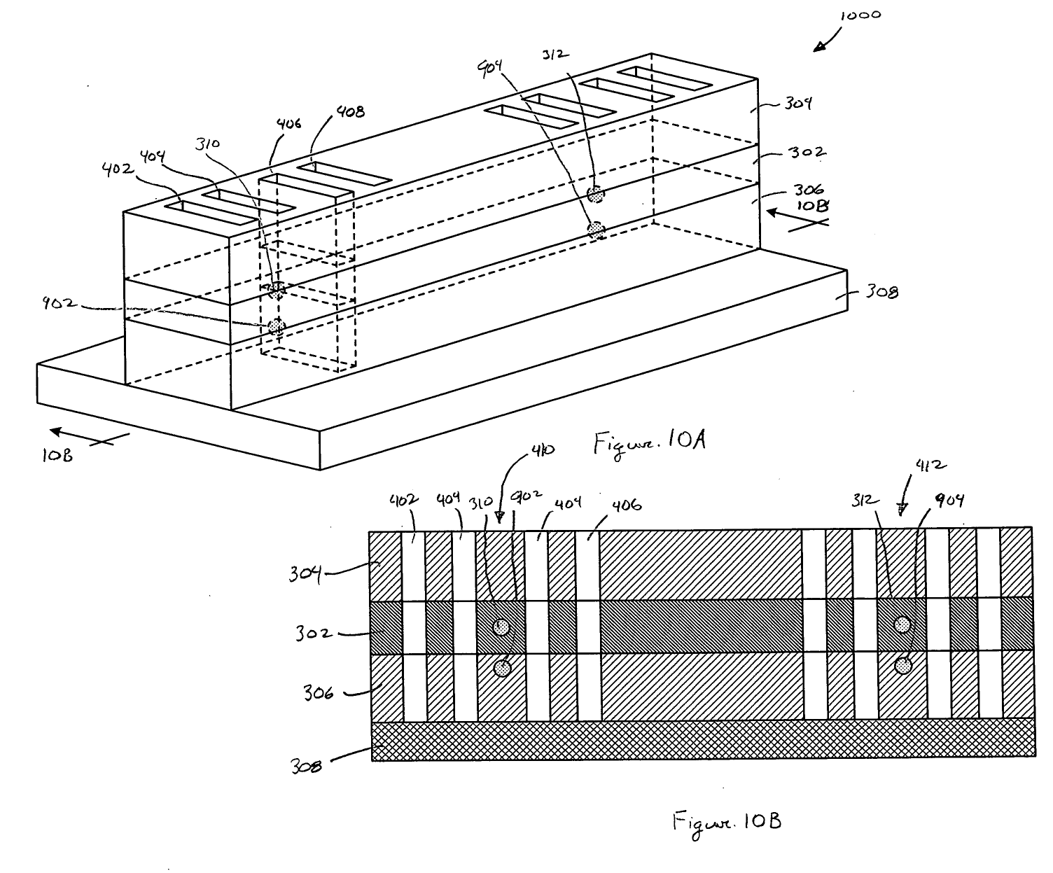

FIG. 10A shows an isometric view of a photonic device 1000 that couples two quantum systems in accordance with embodiments of the present invention. Photonic device 1000 is identical to photonic device 400, shown in FIG. 4, except for quantum systems 902 and 904 positioned in bottom layer 306 beneath QSs 310 and 312, respectively. FIG. 10B shows a cross-sectional view of photonic device 1000 along a line 10B-10B, shown in FIG. 10A, in accordance with an embodiment of the present invention. Radio frequency radiation can be used to couple the electron spin states of QSs 3 10 and 3 12 to nuclear spin states of QSs 902 and 904.

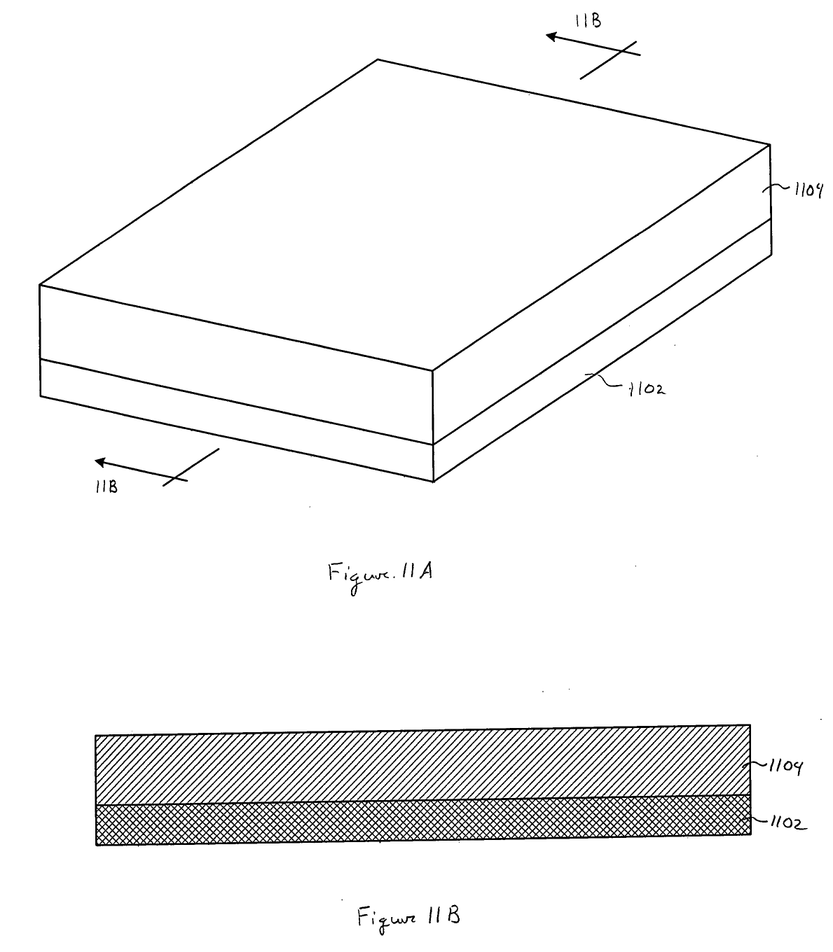

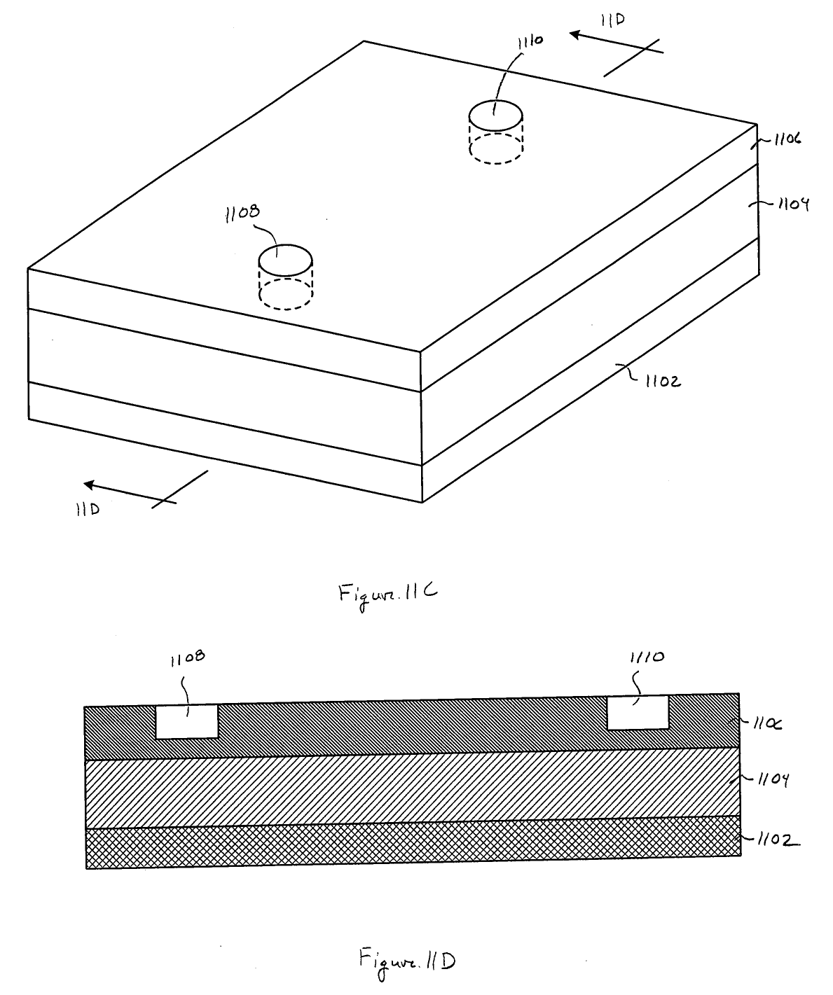

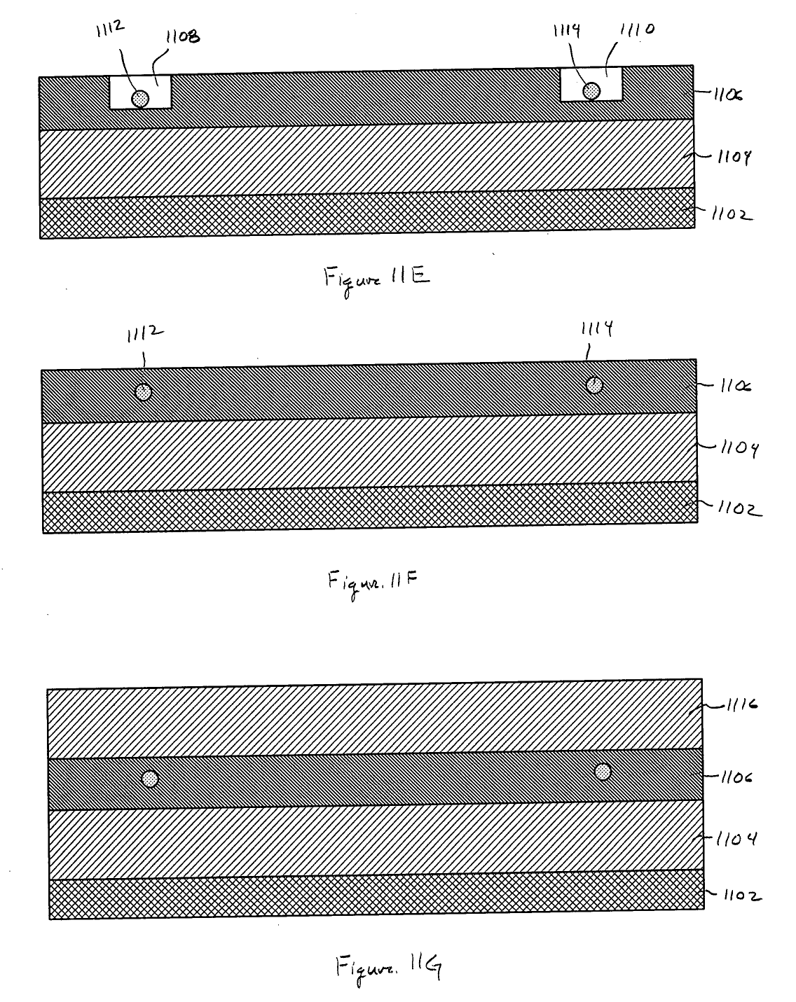

FIGS. 11A-11G show isometric and cross-sectional views associated with a method of fabricating the layers and QSs of the first quantum dot system, shown in FIG. 3, in accordance with an embodiment of the present invention. FIGS. 11A-11B show an isometric and a cross-section view along a line 11A-11A, shown in FIG. 11A, of a bottom semiconductor layer 1104 supported by a substrate 1102. Bottom semiconductor layer 1104 can be comprised of a III-V, a II-VI, or a Group IV semiconductor and can be formed on the top surface of substrate 1102 using molecular beam expitaxy (“MBE”), liquid phase epitaxy (“LPE”), hydride vapor phase epitaxy (“HVPE”), metalorganic vapor phase expitaxy (“MOVPE”), chemical vapor deposition (“CVD”), another suitable expitaxy method, or deposited using wafer bonding.

Next, FIGS. 11C-11D show an isometric and cross-sectional view along a line 11C-11C, of a dielectric transmission layer 1106 on the top surface of bottom semiconductor layer 1104. Transmission layer 1004 can be comprised of a polymer, Al₂O₃, SiO₂, or another suitable dielectric material having relatively lower refractive index than bottom semiconductor layer 1002. The material selected for transmission layer 1106 is based on substantially lattice matching with the lattice of bottom semiconductor layer 1104. For example, when bottom semiconductor layer 1104 is comprised of Si, transmission layer 1106 can be comprised of SiO₂, or when bottom semiconductor layer 1104 is comprised of GaAs, transmission layer 1106 can be comprised of Al₂O₃. Transmission layer 1106 can be formed using CVD, MBE, LPE, HVPE, or MOVPE, or transmission layer 1106 can be deposited using wafer bonding. Also shown in FIGS. 11C-11D are openings 1108 and 1110, which can be formed in transmission layer 1106 using one of many well-known methods, such as reactive ion etching (“RIE”), chemically assisted ion beam etching (“CAIBE”), focused ion beam milling (“FIBM”), photolithography, ion beam lithography, or nanoimprint lithography. Openings 1108 and 1110 may vary in size and shape depending on the size and shape of the QSs deposited in openings 1108 and 1110. For example, opening 1108 can be circular, elliptical, square, rectangular, triangular, or an suitable irregular shape.

Next, as shown in the cross-sectional view of FIG. 11E, QD-based QSs 1112 and 1114 can be formed or deposited in openings 1108 and 1110, respectively. For example, materials that condense into QD-based QSs can be deposited using CVD or MBE on the top surface of transmission layer 1106 and into the openings 1108 and 1110. Chemical mechanical polishing (“CMP”) processes may be used to planarize the top surface of transmission layer 1106 in order to remove the materials formed on the top surface of transmission layer 1106 leaving QD-based QSs 1112 and 1114. QD-based QSs can also be preformed using colloidal synthesis and deposited on the top surface of transmission layer 1106 and into openings 1108 and 1110. CMP can again be used to remove QD-based QSs deposited on the top surface of transmission layer 1106 leaving QSs 1112 and 1114. Color-center-based QSs can also be preformed as described above with reference to FIG. 1 and deposited in openings 1108 and 1110.

Next, as shown in the cross-sectional view of FIG. 11F, material used to form transmission layer 1106 can be deposited over QSs 1112 and 1114 using MBE, LPE, HVPE, MOVPE, CVD, or another suitable expitaxy method, and CMP can be used to planarize the top surface of transmission layer 1106.

Next, as shown in the cross-sectional view of FIG. 11G, a top semiconductor layer 1116 can be formed or deposited on the top surface of transmission layer 1106 using MBE, LPE, HVPE, MOVPE, CVD, or another suitable expitaxy method, or deposited using wafer bonding. Top semiconductor layer 1116 can be identical to bottom semiconductor layer 1104. Finally, RIE, CAIBE, or FIBM can then be used to form the waveguide of photonic device 300, shown in FIG. 3.

In other embodiments of the present invention, RIE, CAIBE, or FIBM can be used to form holes, such as holes 402, 404, 406, and 408 in photonic device 400, shown in FIG. 4, in order to form resonant cavities around QSs.

In other embodiments of the present invention, photonic device 900, shown in FIG. 9, can be fabricated by forming two holes in bottom semiconductor layer 1104, as shown in FIGS. 11A-11B, prior to forming transmission layer 1106, as shown in FIG. 11C-11D. The holes in bottom semiconductor layer 1104 can be formed using RIE, CAIBE, FIBM, photolithography, ion beam lithography, or nanoimprint lithography. In a subsequent step, QSs can then be formed within these holes in accordance with the methods described above with reference to FIG. 11E. The holes can then be back filled using MBE, LPE, HVPE, MOVPE, CVD, or another suitable expitaxy method, and CMP can be used to planarize the top surface of bottom semiconductor layer 1104. The remainder of photonic device 900 can then be formed as described above with reference to FIGS. 11C-11G.

In other embodiments of the present invention, RIE, CAIBE, or FIBM can be used to form holes, such as holes 402, 404, 406, and 408, in photonic device 1000, shown in FIG. 10.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A photonic device comprising:
a top layer;
a bottom layer;
a transmission layer positioned between the top layer and the bottom layer and configured to transmit electromagnetic radiation; and
at least one quantum system embedded within the transmission layer, the at least one quantum system positioned to receive electromagnetic radiation and configured to emit electromagnetic radiation that propagates within the transmission layer.

2. The device of claim 1 wherein the transmission layer further comprises a dielectric material having a lower refractive index than the refractive indexes associated with the top layer and the bottom layer.

3. The device of claim 1 further comprising at least one quantum system embedded in the bottom layer such that the at least one quantum system in the transmission layer is optically coupled to the at least one quantum system embedded in the bottom layer.

4. The device of claim 1 further comprising a number of holes extending through the top layer, the transmission layer, and the bottom such that at least two holes are positioned on one side of the at least one quantum system and at least two holes are positioned an opposite side of the at least one quantum system and are configured to form at least one resonant cavities containing the at least one quantum system.

5. The device of claim 4 wherein the holes can be one of:
rectangular;
square;
round;
elliptical; and
any other shape suitable for forming a resonant cavity around the at least one quantum system.

6. The device of claim 1 wherein the quantum system further comprises one of:
a nanoparticle color center;
a three-level quantum dot;
a four-level quantum dot;
impurity-bound exciton in a semiconductor;
atoms; and
ions.

7. The device of claim 6 wherein the quantum dot further comprise one of:
a III-V semiconductor; and
a II-VI semiconductor.

8. The device of claim 1 wherein the transmission layer further comprises one of:
SiO₂;
Al₂O₃;
Si₃N₄;
a polymer; and
another suitable dielectric material.

9. A photonic antenna comprising a photonic device configured in accordance with claim 1.

10. A method of fabricating a photonic device, the method comprising:
forming a bottom semiconductor layer on a substrate;
forming a transmission layer on the bottom semiconductor layer;
forming at least one opening in the transmission layer;
forming at least one quantum system in the at least one opening; and
forming a top semiconductor layer on the transmission layer.

11. The method of claim 10, wherein forming the bottom semiconductor layer on the substrate further comprises employing one of:
molecular beam expitaxy;
liquid phase expitaxy;
hydride vapor phase expitaxy;
metalorganic vapor phase expitaxy;
chemical vapor deposition;
another suitable expitaxy method; and
wafer bonding.

12. The method of claim 10, wherein forming the transmission layer on the bottom layer further comprises employing one of:
molecular beam expitaxy;
liquid phase expitaxy;
hydride vapor phase expitaxy;
metalorganic vapor phase expitaxy;
chemical vapor deposition;
another suitable expitaxy method; and
wafer bonding.

13. The method of claim 10, wherein depositing the top layer on the transmission layer further comprises employing one of:
molecular beam expitaxy;
liquid phase expitaxy;
hydride vapor phase expitaxy;
metalorganic vapor phase expitaxy;
chemical vapor deposition;
another suitable expitaxy method; and
wafer bonding.

14. The method of claim 10 wherein forming the at least one opening in the transmission layer further comprises employing on of:
reactive ion etching;
focused ion beam milling;
chemically assisted ion beam etching;
photolithography;
ion beam lithography; and
nanoimprint lithography.

15. The method of claim 10 wherein forming the at least one quantum system in the at least one opening further comprises employing one of:
chemical vapor deposition;
molecular beam epitaxy; and
depositing prefabricated quantum systems.

16. The method of claim 15 wherein depositing prefabricated quantum systems further comprises forming quantum dots using colloidal synthesis.

17. The method of claim 10 further comprising:
forming at least one opening in the bottom semiconductor layer; and
depositing at least one quantum system in the at least one opening.

18. The method of claim 17 wherein forming the at least one opening further comprises employing one of:
reactive ion etching;
chemically assisted ion beam etching;
photolithography;
ion beam lithography; and
nanoimprint lithography.

19. The method of claim 17 wherein the quantum system further comprises one of:
a nanoparticle color center;
a three-level quantum dot;
a four-level quantum dot;
impurity-bound exciton in a semiconductor;
atoms; and
ions.
